(19) United States
(12) Patent Application Publication
(10) Pub. No.: US 2003/0174533 A1
(43) Pub. Date: Sep. 18, 2003

(54) Dynamic random access memory (DRAM) and method of operating the same

(76) Inventor: Munehiro Ito, Kanagawa (JP)

Correspondence Address: Darryl G. Walker, WALKER & SAKO, LLP, Suite 235, 300 South First Street, San Jose, CA, 95113, US

(21) Appl. No.: 10/377,955

(22) Filed: Mar. 3, 2003

(30) Foreign Application Priority Data
Mar. 4, 2002 (JP) 2002-057968

(51) Int. Cl. G11C 11/24

(52) U.S. Cl. 365/149

(57) ABSTRACT

A technique is disclosed that can decrease a dynamic random access memory (DRAM) write access time to a selected memory cell while preventing destruction of write data to a non-selected memory cell connected to the same word line. After a sense amplifier (5ⱼ₊₁) has amplified a potential difference between non-selected bit lines (BLⱼ₊₁ and /BLⱼ₊₁), a write buffer (8) can drive selected bit lines (BLⱼ and /BLⱼ) according to write data for a selected memory cell (MCᵢⱼ). After a write buffer (8) has started to drive selected bit lines (BLⱼ and /BLⱼ), a sense amplifier (5ⱼ) can start to amplify the potential difference between such selected bit lines (BLⱼ and /BLⱼ).

### TECHNICAL FIELD

The present invention relates generally to dynamic random access memories (DRAMs), and more particularly to write operations for DRAMs.

### BACKGROUND OF THE INVENTION

A common dynamic random access memory (DRAM) memory cell is that which includes one transistor and one capacitor. FIG. 4 shows a memory core 100 of a conventional DRAM. Such a conventional memory core 100 includes a memory cell 101, bit lines BL and /BL, a word line WL, a precharge circuit 102, a sense amplifier 103, and a column switch 104.

A memory cell 101 includes a memory cell capacitor 101a and a metal-oxide-semiconductor (MOS) transistor 101b. A memory cell capacitor 101a can store electric charge corresponding to a data value to be stored by a memory cell 101. When a data “1” is to be stored, electric charge can be accumulated within a memory cell capacitor 101a. When a data “0” is to be stored, no electric charge can be accumulated in memory cell capacitor 101a.

A MOS transistor 101b of a memory cell 101 can have one of its source/drain connected to memory cell capacitor 101a, and another of its source/drain connected to a bit line BL. A gate of MOS transistor 101b can be connected to a word line WL. If a word line WL is activated, a memory cell capacitor 101a is electrically connected to bit line BL.

In memory core 100, a bit line /BL extends parallel to bit line BL. It is understood that other memory cells that are activated by other word lines (not shown) can be connected to bit line /BL. Memory cells connected to bit line /BL are not shown in FIG. 4. A bit line BL and bit line /BL are connected to precharge circuit 102.

Precharge circuit 102 can precharge bit lines BL and /BL to the same potential. The precharge circuit 102 includes n-type MOS (NMOS) transistors 102a, 102b and 102c. NMOS transistor 102a can be provided between a bit line BL and a precharge line 105. NMOS transistor 102b can be provided between a bit line /BL and a precharge line 105. Precharge line 105 has a potential of V_{DD}/2 that corresponds to one half of a power source potential V_{DD}. NMOS transistor 102c can be provided between a bit line /BL and bit line BL. A precharge activation signal EQ is supplied to the gates of NMOS transistors 102a, 102b and 102c. In such an arrangement, when precharge activation signal EQ is high, precharge circuit 102 can be activated, and both of bit lines BL and /BL can be supplied with a potential of V_{DD}/2.

A bit line BL and bit line /BL can also be connected to a sense amplifier 103. A sense amplifier 103 can be formed from by complementary MOS (CMOS) inverters 103a and 103b, a p-type MOS (PMOS) transistor 103c, and an NMOS transistor 103d. CMOS inverter 103a is formed by NMOS transistor 103e and PMOS transistor 103f, and CMOS inverter 103b is formed by NMOS transistor 103g and PMOS transistor 103h. An output terminal of CMOS inverter 103a is connected to an input terminal of CMOS inverter 103b. Conversely, an output terminal of CMOS inverter 103b is connected to an input terminal of CMOS inverter 103a. CMOS inverters (103a and 103b) are connected to a power source line 106 by PMOS transistor 103c. Power source line 106 can have the power supply potential V_{DD}. CMOS inverters (103a and 103b) are connected to a ground line 107 by NMOS transistor 103d. Ground line 107 can have the power supply potential V_{SS}. A sense amplifier activation signal SAS is supplied directly to a gate of NMOS transistor 103d, and to a gate of PMOS transistor 103c by way of inverter 108.

When a sense amplifier activation signal SAS is active (e.g., high in this case), sense amplifier 103 can pull up one bit line (e.g., BL or /BL) to the power source potential V_{DD} and the other bit line (e.g., /BL or BL) to ground potential V_{SS}.

Bit lines BL and /BL are further connected to a column switch 104. Column switch 104 includes NMOS transistor 104a and NMOS transistor 104b. NMOS transistor 104a is connected between bit line BL and a data bus IO. NMOS transistor 104b is connected between bit line /BL and a data bus /IO. A column switch signal CSW can be applied to the gates of NMOS transistors 104a and 104b.

When column switch signal CSW is active (e.g., high in this case) bit lines BL and /BL are connected to data buses IO and /IO, respectively.

Data buses IO and /IO are connected to a write buffer 109. A write buffer 109, according to write data, drives data buses IO and /IO to complementary potentials (e.g., high and low).

Data buses IO and /IO are further connected to a read buffer (not shown). A read buffer may output read data from the memory core 100.

Referring now to FIG. 5, a timing diagram is set forth showing a conventional data write operation to memory cell 101 of memory core 100 shown in FIG. 4. Initially, a precharge activation signal EQ can be high, thus bit lines BL and /BL can be precharged to the potential of V_{DD}/2.

When a write command WCMD is issued to the DRAM containing memory core 100, write buffer 109 drives data buses IO and /IO to complementary values (high/low or low/high) according to write data. In addition, the precharge activation signal EQ can fall to a low level bringing bit lines BL and /BL into an high impedance state.

Subsequently, a word line WL can be pulled to a high level to activate NMOS transistor 101b. In general, such a high level can be a potential greater than that of V_{DD}. When NMOS transistor 101b is activated, electric charge can be exchanged between memory cell capacitor 101a and bit line BL. Such an exchange of charge can develop a differential voltage between bit line BL and /BL. In this particular example, it will be assumed that the differential voltage results in the potential of bit line BL being slightly higher than that of /BL.

Subsequently, sense amplifier activation signal SAS can be pulled to a high voltage to activate sense amplifier 103. When sense amplifier 103 is activated, the differential voltage between BL and /BL is amplified. Such an amplification results in bit lines BL and /BL being driven to complementary voltages (V_{DD} and V_{SS}). In this example, assuming the above differential voltage, bit line BL is pulled to a power source voltage V_{DD}, while a bit line /BL is pulled to a ground voltage V_{SS}.

Subsequently, column selection signal CSW can be pulled to a high potential to activate column switches 104a and 104b. Bit line BL is electrically connected to data bus IO and bit line /BL is electrically connected to data bus /IO.

Once bit lines BL and /BL have been connected to data buses IO and /IO, respectively, bit lines BL and /BL can be driven to complementary potentials by write buffer 109 according to write data.

In this state, bit line BL is connected to memory cell capacitor 101a. Thus, the potential corresponding to write data can be supplied to memory cell capacitor 101a to thereby write data to memory cell 101.

Subsequently, the column selection signal CSW, the word line WL and sense amplifier activation signal SAS are pulled down to a low potential. Further, a precharge activation signal EQ can return to a high level. This can complete the above described conventional write operation.

In the conventional DRAM arrangement above, in the event write data is complementary to data already stored in a memory cell 101, potentials of bit lines BL and /BL, established by operation of sense amplifier 103, will have to be forcibly inverted by write buffer 109.

For example, it will be assumed that a data value of “1” has been previously written into memory cell 101 and a data value of “0” is new write data for the memory cell 101. In this case, at the time word line WL is activated, electric charge is supplied from memory cell 101 to bit line BL, so that the potential of bit line BL is higher than that of /BL. In this state, when the sense amplifier 103 is activated, but line BL is driven to a high potential (corresponding to the previously written data values of “1”) and bit line /BL is driven to a low potential. However, for the writing of new data value “0” to the memory cell 101, the write buffer 109 must overcome the driving ability of sense amplifier 103 to change the potential of bit line BL from a high potential to a low potential, and change the potential of bit line /BL from a low potential to a high potential.

A conventional write operation, in which a write amplifier 109 must overcome the driving power of a sense amplifier 103 to thereby invert the potentials of bit lines BL and /BL, can be undesirable as such operations can add to an overall write time in a conventional DRAM.

One technique for avoiding the inversion of bit line potentials when “inverted data” (data complementary to currently stored data) is written to a memory cell is disclosed in Japanese Patent Application Laid-Open Koho No. 101863 of 2001 (herein after JP 2001-101863). FIG. 6 shows a write operation for a DRAM according to this conventional technique.

Referring now to FIG. 6, in an initial state, a precharge activation signal EQ can be at a high voltage. Consequently, bit lines BL and /BL can be driven to a potential V_{DD}/2.

After a precharge activation signal EQ has been pulled to a low voltage, word line WL can be pulled up to turn on NMOS transistor 101b of memory cell 101, thereby connecting memory cell capacitor 101a to bit line BL. As a result, the potential of bit line BL can be changed to thereby produce a differential voltage between bit line BL and bit line /BL.

Subsequently, the column selection signal CSW can be pulled to a high potential to activate column switches 104a and 104b. When column switches (104a and 104b) are activated, bit line BL is electrically connected to data bus IO, while bit line /BL is electrically connected to data bus /IO.

When bit lines BL and /BL are connected to data buses IO and /IO, respectively, bit lines BL and /BL can be driven to potentials corresponding to write data by write buffer 109. Thus, one of bit lines BL or /BL can be driven to a high potential, while one of bit lines /BL or BL can be driven to a low potential. It is noted that at this time sense amplifier activation SAS can be low, and sense amplifier 103 is not activated. Thus, when write buffer 109 drives bit lines BL and /BL, such a writing can occur rapidly, regardless of what data value (e.g., “1” or “0”) has been previously stored in memory cell capacitor 101a.

In addition, when bit lines BL and /BL are driven to complementary potentials by write buffer 109, memory cell capacitor 101a can be connected to bit line BL. Thus, the potential corresponding to the write data is supplied to memory cell capacitor 101a, thereby writing data to memory cell 101.

Subsequent to such a writing of data to memory cell 101, sense amplifier activation signal SAS is pulled to a high voltage to activate sense amplifier 103. Sense amplifier 103 can then drive bit lines BL and /BL according to a difference in potential between such bit lines BL and /BL. However, at this time bit lines BL and /BL have already been driven to complementary values by write amplifier 109. Thus, sense amplifier 103 will supply the same potential as that of write buffer 109 to bit lines BL and /BL.

Subsequently, the column selection signal CSW, the word line WL and sense amplifier activation signal SAS are pulled down to a low potential. Further, a precharge activation signal EQ can return to a high level. This can complete the above described conventional write operation of FIG. 6

In the conventional write operation of FIG. 6, because sense amplifier 103 and write buffer 109 drive bit line BL and bit line /BL to the same complementary potentials, a forcible inversion of bit line potential can be avoided, regardless of the data value to be written to a memory cell.

However the technique of JP 2001-101863 can have drawbacks. In particular, in such a write operation, data stored in other memory cells connected to the same activated word line may be destroyed.

Referring now to FIG. 7, in a conventional memory core, a number of bit lines BL and bit lines /BL can be situated in an alternating arrangement. In addition, a coupling capacitance Cₚₐᵣₐ can exist between and bit line BL and an adjacent bit line /BL. In a write operation, like that of JP 2001-101863, when data is written for one memory cell, data for another memory cell can be destroyed due to the coupling capacitance Cₚₐᵣₐ. Such an undesirable event can occur as follows.

In the following description, it will be assumed that a destination memory cell for write data is memory cell 101ᵢ. Thus, memory cell 101ᵢ will be referred to the selection memory cell 101ᵢ. Further, memory cell 101ᵢ₊₁ connected to the same word line WL as selection memory cell 101ᵢ and is adjacent to selection memory cell 101ᵢ and will be referred to as the non-selection memory cell 101ᵢ₊₁. In addition, parallel bit lines connected to selection memory cell 101ᵢ, bit lines BLᵢ and /BLᵢ, will be referred to as selection bit lines. In a similar fashion, parallel bit lines connected to non-selection memory cell 101ᵢ₊₁, bit lines BLᵢ₊₁ and /BLᵢ₊₁ will be referred to as non-selection bit lines. Still further, a column switch 104ᵢ connected to selection bit lines BLᵢ and /BLᵢ will be referred to as the selection column switch, and a column switch 104ᵢ₊₁ connected to non-selection bit lines BLᵢ₊₁ and /BLᵢ₊₁ will be referred to as the non-selection column switch.

Referring now to FIG. 7 in conjunction with FIG. 8, when word line WL has been pulled to a high level, memory cell capacitor 101aᵢ of selection memory cell 101ᵢ is connected to selection bit line BLᵢ, and memory cell capacitor 101aᵢ₊₁ of non-selection memory cell 101ᵢ₊₁ is connected to non-selection bit line BLᵢ₊₁. As shown in FIG. 8, the potentials of selection bit line BLᵢ and non-selection bit line BLᵢ₊₁ can change slightly according to the data value stored in selection memory cell 101ᵢ and non-selection memory cell 101ᵢ₊₁, respectively.

A column selection signal CSWᵢ then rises to a high level. When selection column switch 104ᵢ has been activated by column selection signal CSWᵢ, selection bit lines BLᵢ and /BLᵢ can be driven to complementary voltages by a write buffer 109 according to a data value to be written into selection memory cell 101ᵢ. In the example of FIG. 8, it will be assumed that selection bit line BLᵢ is pulled down to a low potential, while selection bit line /BLᵢ is pulled up to a high potential.

When selection bit lines BLᵢ and /BLᵢ are driven to complementary values by write buffer 109, non-selection bit line BLᵢ₊₁ is in a floating state. Due to coupling capacitance Cₚₐᵣₐ between selection bit line /BLᵢ and non-selection bit line BLᵢ₊₁, the potential of non-selection bit line BLᵢ₊₁ can vary as the potential of selection bit line /BLᵢ varies. This effect is shown in FIG. 8 by the potential of non-selection bit line BLᵢ₊₁ rising as the potential of selection bit line /BLᵢ rises.

As shown in FIG. 8, due to the above effect, a relative potential between non-selection bit lines BLᵢ₊₁ and /BLᵢ₊₁ can be reversed depending upon how the potential of non-selection bit line /BLᵢ₊₁ is changed due to coupling capacitance Cₚₐᵣₐ.

Referring still to FIG. 8, following the driving a selection bit lines BLᵢ and /BLᵢ by a write buffer, sense amplifier activation signal SAS can be pulled high, thereby activating sense amplifier 103ᵢ and sense amplifier 103ᵢ₊₁. Ideally, sense amplifier 103ᵢ₊₁ drives non-selection bit lines BLᵢ₊₁ and /BLᵢ₊₁ according to the data value previously stored in non-selection memory cell 101ᵢ₊₁. In this way, a data value in non-selection memory cell 101ᵢ₊₁ can be restored.

However as noted above, due to a coupling capacitance Cₚₐᵣₐ, at the time sense amplifier 103ᵢ₊₁ is activated, a relative potential between non-selection bit lines BLᵢ₊₁ and /BLᵢ₊₁ may be reversed. Consequently, a restore operation for non-selection memory cell 101ᵢ₊₁ can result in the wrong data being written into non-selection memory cell 101ᵢ₊₁.

Thus, in an arrangement like that of JP 2001-101863, it is possible that data stored in a non-selection memory cell may be destroyed due to a coupling capacitance Cₚₐᵣₐ present between one bit line (e.g., BL) and an adjacent bit line (e.g., /BL).

In light of the above, it would be desirable to arrive at some way of reducing an access time required for a write operation. Preferably, such an approach can also prevent destruction of data stored in a non-selection memory cell connected to the same word line of a (selection) memory cell accessed by a write operation.

### SUMMARY OF THE INVENTION

The present invention includes a dynamic random access memory (DRAM) having a plurality of memory cells that include transfer switches and capacitors, a plurality of bit lines, each being electrically connected to at least one of the capacitors by the activation of a corresponding transfer switch, a plurality of sense amplifiers connected to corresponding bit lines, a plurality of column switches connected to the plurality of bit lines, and a decoder for selecting a selection bit line from the plurality of bit lines. The DRAM can also include a control unit for controlling the transfer switches, the column switches, and the sense amplifiers. In a write operation, the control unit can activate the transfer switches, subsequently activate a non-selection sense amplifier that drives a non-selection bit line that is different than the selection bit line, then subsequently activate the column switch connected to the selection bit line to electrically connect a write buffer to the selection bit line. After driving the selection bit line with the write buffer, a control unit can subsequently activate a selection sense amplifier that drives the selection bit line.

As understood from the above, in a DRAM according to the present invention, a selection sense amplifier can drive a selection bit line after a write buffer begins to drive the selection bit line according to a write data value. Thus, the selection sense amplifier can drive the selection bit line in the same potential direction as the write buffer. Consequently, a forcible inversion of a potential of a selection bit line (with reference to a precharge potential, for example) can be avoided. This can result in reducing the access time required for a write operation.

According to one aspect of the embodiments, a write buffer can drive the selection bit line from an initial potential through a middle potential, about midway between a high and low logic level, when a write data value is different than a stored data value. In addition, a control unit can activate a selection sense amplifier at essentially the same time that the selection bit line transitions through such a middle potential. In such an arrangement, a driving ability of both a write buffer and selection sense amplifier can establish a logic value of a selection bit line. This can further reduce an access time for a write operation.

According to another aspect of the embodiments, a DRAM can also include a plurality of complementary bit lines each corresponding to one of the bit lines, a first bias line and second bias line connected to each of the sense amplifiers. The first and second bias lines can be driven to a first power source potential and second power source potential, respectively, when the sense amplifier is activated, and driven to a predetermined precharge potential when the sense amplifiers are deactivated.

According to another aspect of the embodiments, each sense amplifier can include a first inverter coupled to a first terminal and second terminal. The first inverter has an input, and an output coupled to one of the bit lines. Each sense amplifier can also include a second inverter coupled to the first terminal and second terminal, that has an output coupled to one of the complementary bit lines and to the input of the first inverter, and an input coupled to the output of the first inverter. Each sense amplifier further includes a first switch that couples the first bias line to the first terminal when the sense amplifier is activated, and isolates the first bias line from the first terminal after the first bias line is driven to a predetermined precharge potential.

According to another aspect of the embodiments, each sense amplifier can further include a second switch that couples the second bias line to the second terminal when the sense amplifier is activated, and isolates the second bias line from the second terminal after the second bias line is driven to a predetermined precharge potential.

The present invention may also include a DRAM having a plurality of memory cells, a plurality of bit lines coupled to the plurality of memory cells, a decoder for selecting a selection bit line from the plurality of bit lines, a plurality of sense amplifiers coupled to the bit lines, and a control unit. In a write operation, a control unit can control the sense amplifiers by activating a selection sense amplifier, connected to the selection bit line, at a different time than at least one non-selection sense amplifier, that is not connected to the selection bit line. In one particular arrangement, such a DRAM can activate the at least one non-selection sense amplifier to restore data for memory cells that are not written to. The timing of such a restore operation can prevent destruction of data in such cells that could otherwise occur in a write operation.

According to one aspect of the embodiments, a control unit can activate the selection sense amplifier after activating the at least one non-selection sense amplifier in the write operation.

According to another aspect of the embodiments, a DRAM may also include a plurality of column switches disposed between the bit lines and a data bus. In addition, the control unit, in the write operation, can activate the at least one non-selection sense amplifier before activating a selection column switch coupled to the selection bit line, and can activate the selection sense amplifier no sooner than the activation of the selection column switch.

According to another aspect of the embodiments, a control unit can activate the selection sense amplifier at a different time than at least one non-selection sense amplifier in response to an address signal.

According to another aspect of the embodiments, a control unit can activate the selection sense amplifier by activating a sense amplifier activation signal corresponding to the selection sense amplifier after activating a sense amplifier activation signal corresponding to the non-selection sense amplifier.

The present invention may also include a method of writing data to a DRAM that includes the steps of:

(a) selecting a selection bit line from a plurality of bit lines;

(b) activating memory cell transfer switches to couple memory cell capacitors to the bit lines;

(c) after activation of the transfer switches, activating a non-selection sense amplifier coupled to a non-selection bit line to drive the non-selection bit line, the non-selection bit line being different than the selection bit line;

(d) after activating the non-selection sense amplifier, driving the selection bit line with a write amplifier through a column switch connected to the selection bit line; and

(e) after the driving of the selection bit line with the write amplifier begins, driving the selection bit line with a selection sense amplifier coupled to the selection bit line.

According to one aspect of the embodiments, in such a method of writing data to a DRAM, a step (e) can be executed at essentially the same time the selection bit line transitions from an initial potential through a middle potential by operation of the write amplifier. A middle potential can be essentially mid-way between a high and low logic value for the selection bit line.

According to another aspect of the embodiments, in such a method of writing data to a DRAM, a step (e) can include:

(f) driving a first bias line and second bias line connected to the selection sense amplifier toward a first source potential and second source potential, respectively; and

(g) activating a first switch to supply the first source potential to a first terminal of the selection sense amplifier, and activating a second switch to supply the second source potential to a second terminal of the selection sense amplifier.

According to another aspect of the embodiments, a method of writing data to a DRAM can further include the steps of:

(h) after step (e), driving a first bias line and second bias line to a predetermined precharge potential that is between first and second source potentials; and

(i) after step (h), deactivating a first switch to isolate the first source potential from the first terminal of the selection sense amplifier, and deactivating the second switch to isolate the second source potential from the second terminal of the selection sense amplifier.

According to another aspect of the embodiments, in such a method of writing data to a DRAM, a step (e) can include delaying a sense amplifier activation signal for the selection sense amplifier in response to an address value.

The present invention may also include a method of writing data to a DRAM having the steps of:

(a) selecting a selection bit line from a plurality of bit lines;

(b) activating a plurality of transfer switches to electrically connect capacitors to corresponding bit lines; and

(c) after step (b), activating a plurality of sense amplifiers coupled to the bit lines, including activating a selection sense amplifier coupled to the selection bit line at a different time than a non-selection sense amplifier coupled to a non-selection bit line that is different than the selection bit line.

In one particular arrangement, such a method can activate the at least one non-selection sense amplifier to restore data for memory cells that are not written to. The timing of such a restore operation can prevent destruction of data in such cells that could otherwise occur in a write operation.

According to one aspect of the embodiments, in such a method of writing data to a DRAM, a step (c) can include activating the selection sense amplifier after the non-selection sense amplifier.

According to another aspect of the embodiments, in such a method of writing data to a DRAM, a step (a) can include selecting the selection bit line in response to an address value; and a step (c) can include differentiating activation times of the selection sense amplifier and the non-selection sense amplifier according to at least a portion of the address value.

According to another aspect of the embodiments, a method of writing data to a DRAM may further include step (d) of connecting a write amplifier to the selection bit line before activating the selection sense amplifier.

According to another aspect of the embodiments, in such a method of writing data to a DRAM a step (c) can include

(c1) the non-selection sense amplifier driving the non-selection bit line according to a potential established by a non-selection memory cell coupled to the non-selection bit line, and

(c2) after step (c1), the selection sense amplifier driving the selection bit line according to a potential established by a write amplifier.

### BRIEF DESCRIPTION OF THE DRAWINGS

FIG. 1 is a diagram showing a dynamic random access memory (DRAM) according to one embodiment of the present invention.

FIG. 2 is a detailed diagram showing a memory cell array, precharge unit, sense amplifier unit, and column switch unit according to an embodiment of the present invention.

FIG. 3 is a timing diagram showing a write operation of a DRAM according to an embodiment of the present invention.

FIG. 4 is a diagram showing a conventional DRAM memory core.

FIG. 5 is a timing diagram showing a conventional DRAM write operation.

FIG. 6 is a timing diagram showing another conventional DRAM write operation.

FIG. 7 is a diagram showing a memory core of a conventional DRAM.

FIG. 8 is a timing diagram showing another conventional DRAM write operation.

### DETAILED DESCRIPTION OF THE EMBODIMENTS

The present invention will hereinafter be described in more detail on the basis of various particular embodiments with reference to accompanying figures.

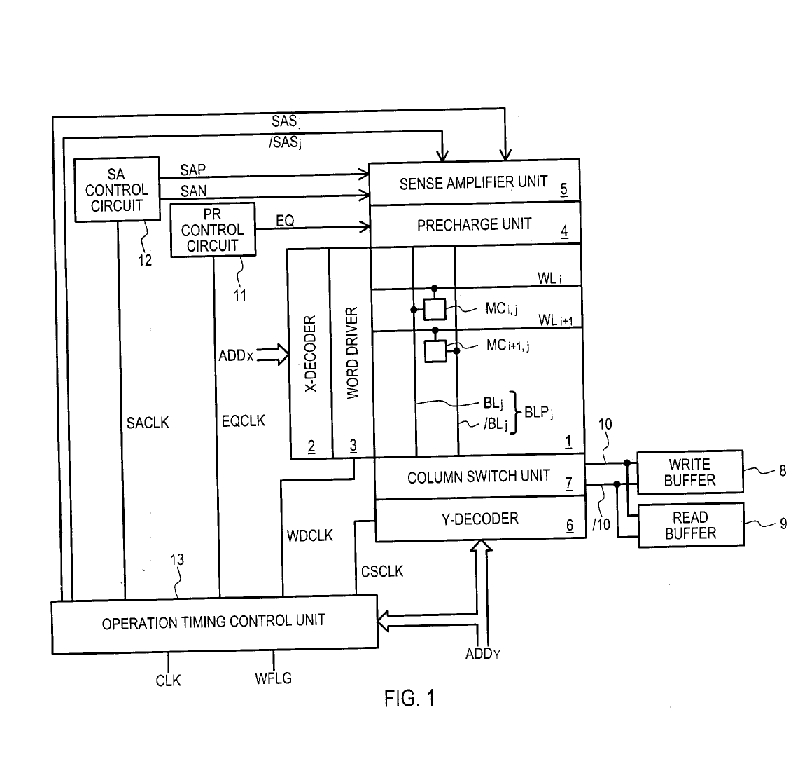

FIG. 1 is a diagram showing a dynamic random access memory (DRAM) according to one embodiment of the present invention. Such a DRAM can include a memory cell array 1 for storing data.

A memory cell array 1 can include a number of memory cells, word lines that extend in a row direction and bit lines that extend in a column direction. Memory cells MC may be arranged in an “m×n” matrix. There may be “m” word lines, “n” bit lines BL, and “n” bit lines /BL. In the following description, among the m word lines, a word line WLᵢ will be distinguished, where “i” can be an arbitrary natural number equal to or greater than 1 and smaller than or equal to “m”). In addition, among the n bit lines BL and /BL, bit lines BLⱼ and /BLⱼ will be distinguished, where “j” can be an arbitrary natural number equal to or greater than 1 and smaller than or equal to “n”). Bit lines BL and /BL can extend in an alternating fashion in the column direction, and bit lines BLⱼ and /BLⱼ can be a bit line pair BLPⱼ. In operation, bit lines BLⱼ and /BLⱼ can carry complementary data values.

Memory cells MC of a memory cell array 1 can be connected to a bit line BL or /BL as well as a word line. In FIG. 1, memory cells MC will be distinguished by subscripts of a corresponding word line and bit line. Thus, memory cell MCᵢⱼ can be connected to a word line WLᵢ and bit line BLⱼ.

Thus, it is understood that a memory cell array 1 can include memory cells MC_{i,1} to MC_{i,n} connected to a particular word line WLᵢ. Such memory cells MC_{i,1} to MC_{i,n} can be connected to bit lines BL₁ to BLₙ or bit lines /BL₁ to /BLₙ, respectively. Even more particularly, if a memory cell MC_{fj′} is connected to a bit line BL_{j′}, other memory cells connected to a same word line WL_{f} can be connected to a corresponding bit line BL. That is, memory cells MC_{f,1} to MC_{f,n} can be connected to bit lines BL₁ to BLₙ, respectively. Likewise, if such a memory cell MC_{fj′} were connected to a bit line /BL_{j′}, other memory cells connected to a same word line WL_{f} can be connected to a corresponding bit line /BL. That is, memory cells MC_{f,1} to MC_{f,n} can be connected to bit lines /BL₁ to /BLₙ, respectively.

The DRAM of FIG. 1 may also include an X-decoder 2, a word driver 3, a precharge unit 4, a sense amplifier unit 5, a Y-decoder 6, a column switch unit 7, a write buffer 8, and a read buffer 9. Such sections can enable access to a memory cell array 1.

An X-decoder 2 can select a word line WL₁ to WLₘ based on an address signal ADDₓ. A word line WL selected by an X-decoder 2 will be referred to herein as a selection word line WL.

A word driver 3 can pull up a word line WL selected by an X-decoder 2. In general, a word driver 3 may pull a selected word line WL to a potential higher than a power source potential V_{DD}.

A precharge unit 4 can precharge bit lines BL and /BL to a precharge potential, such as V_{DD}/2 for example, when memory cells are not accessed or when a refresh operation is not occurring for such memory cells.

A sense amplifier unit 5 can amplify the potential difference between a bit line BL and corresponding bit line /BL of a bit line pair BLP. Such an amplification can pull one such bit line high (e.g., a power source voltage V_{DD}), and the other bit line low (e.g., a ground potential V_{SS}).

A Y-decoder 6 can select one of bit line pairs BLP₁ to BLPₙ based on a Y address signal ADD_{y}. A pair of bit lines selected by a Y-decoder 6 will be referred herein as a selection bit line pair BLP. Further, bit lines BL and /BL included in a selection bit line pair BLP will be referred to herein as selection bit line BL and selection bit line /BL.

A column switch unit 7 can connect a selection bit line BL and selection bit line /BL to a data bus IO and data bus /IO, respectively.

A write buffer 8 can be used in a data write operation for a DRAM. In a write operation, data can be written to a memory cell connected a selection word line WL and a selection bit line BL (or selection bit line /BL). Such a memory cell MC will be referred to as a selection memory cell MC hereinafter. A write buffer 8 can drive one data bus (IO or /IO) high and the other data bus (/IO or IO) low in response to a data value to be written.

A read buffer 9 can be used to read data from a DRAM. In a read operation, data can be read from a selection memory cell MC. A read buffer 9 can receive data from a selection memory cell MC by way of a selection bit lines BL and /BL and data buses IO and /IO, and output such data from a DRAM.

The DRAM of FIG. 1 also includes a sense amplifier control circuit 12, a precharge control circuit 11, and an operation timing control unit 13 for controlling a sense amplifier unit 5, a precharge unit 4, and a word driver 3.

A precharge control circuit 11 can supply a precharge activation signal EQ to a precharge unit 4. While a precharge activation signal EQ has one value (e.g., a high potential) a precharge unit 4 can be activated, and a bit line BL and /BL can be supplied with a precharge potential (e.g., V_{DD}/2).

A sense amplifier control circuit 12 can be connected to a sense amplifier unit 5 through sense amplifier bias lines SAP and SAN. While a DRAM is not performing a write operation, or read operation, or refresh operation, a sense amplifier control circuit 12 can pull sense amplifier bias lines SAP and SAN to a potential V_{DD}/2. However, in a write operation, read operation, or refresh operation, a sense amplifier control circuit 12 can pull a sense amplifier bias line SAP to a power source potential V_{DD}, while it pulls down a sense amplifier bias line SAN to a ground potential V_{SS}. When a sense amplifier bias line SAP is pulled to a power source potential V_{DD} and a sense amplifier bias line SAN is pulled to a ground potential V_{SS}, an activation of a sense amplifier unit 5 can be complete. As will be described in more detail below, a sense amplifier unit 5 can amplify a potential difference between a bit line BL and /BL when activated by a sense amplifier activation signal SAS.

An operation timing control unit 13 can control the operation of a word driver 3, a sense amplifier unit 5, a Y-decoder 6, a precharge control circuit 11, and a sense amplifier control circuit 12. An operation timing control unit 13 may receive an internal clock signal CLK, which can establish a reference timing for the above-mentioned circuits. An operation timing control unit 13 can generate a word driver clock signal WDCLK, a Y-decoder clock signal CSCLK, a precharge control clock signal EQCLK, and a sense amplifier bias control clock signal SACLK synchronously with an internal clock signal CLK. A word driver clock signal WDCLK can prescribe the operation timing of a word driver 3. A Y-decoder clock signal CSCLK can prescribe the operation timing of a Y-decoder 6. A precharge control clock signal EQCLK can prescribe the operation timing of a precharge control circuit 11. A sense amplifier bias control clock signal SACLK can prescribe the operation timing of a sense amplifier control circuit 12.

An operation timing control unit 13 may also generate sense amplifier activation signals SAS₁ to SASₙ and /SAS₁ to /SASₙ, which can prescribe the timing at which a sense amplifier unit 5 starts to amplify the potential difference between bit lines BL and bit line /BL. It is understood that sense amplifier activation signals SAS₁ to SASₙ may be referred to generally as sense amplifier activation signals SAS. Similarly, sense amplifier activation signals /SAS₁ to /SASₙ, may be referred to generally as sense amplifier activation signals /SAS. Sense amplifier activation signals SASⱼ and /SASⱼ of sense amplifier activation signals SAS and /SAS, can have voltages that are complementary to one another. Thus, when a sense amplifier activation signal SASⱼ is driven “high” and a sense amplifier activation signal /SASⱼ is driven “low”, respectively, a potential difference between a bit line BLⱼ and /BLⱼ can begin to be amplified.

The operation of a timing control unit 13 can change depending upon whether a DRAM is carrying out a write operation or another type of operation. In one arrangement, a write operation can be distinguished from other operations by a write flag WFLG received by an operation timing control unit 13.

When a DRAM carries out a write operation, an operation timing control unit 13 can change the timing at which amplification of a potential between a bit line BL and /BL is started for a selection bit line pair BLP. In particular, a Y-address ADD_{y} can be input to an operation control timing unit 13. From such information, an operation control timing unit 13 can determine which bit line pair is a selection bit line pair.

In contrast, when a DRAM carries out a read and/or refresh operation, an operation control timing unit 13 can start the amplification of a potential between a bit line BL and /BL at the same time, different from that of a write operation.

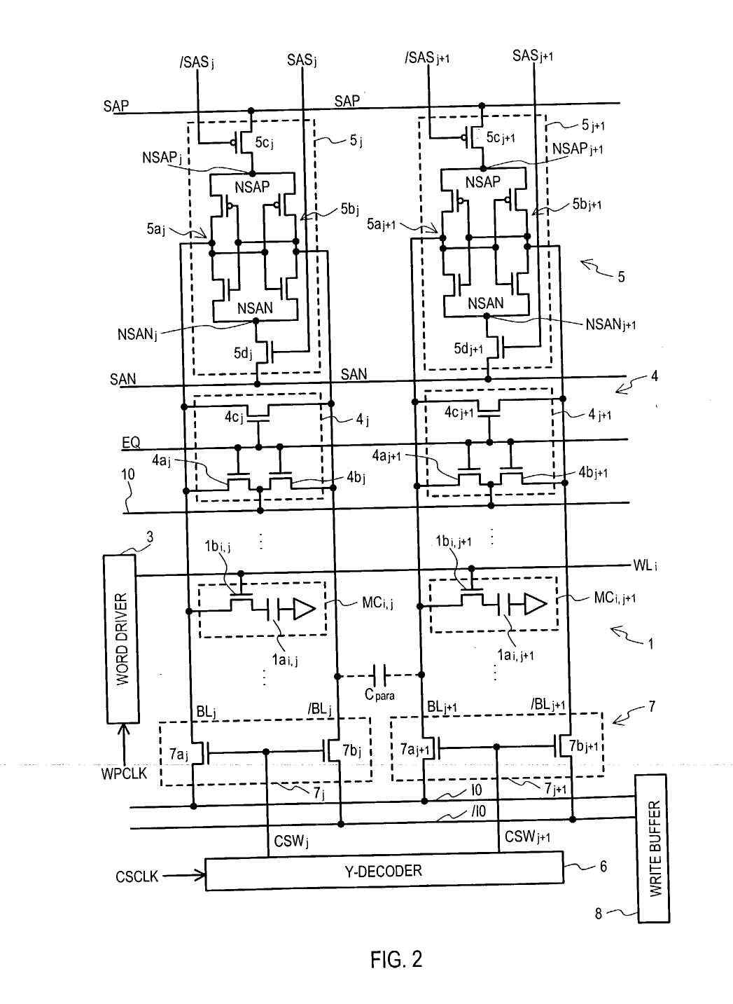

Next, the configuration of a memory cell array 1, a precharge unit 4, a sense amplifier unit 5, and a column switch unit 7, according to one embodiment, will be described in more detail with reference to FIG. 2.

FIG. 2 shows in more detail a memory cell array 1, a precharge unit 4, a sense amplifier unit 5, and a column switch unit 7, according to one embodiment. Within a memory cell array 1, each memory cell (e.g., MCᵢⱼ) can include a memory cell capacitor (e.g., 1aᵢⱼ) and a memory cell transistor (e.g., 1bᵢⱼ). A memory cell capacitor (e.g., 1aᵢⱼ) can accumulate electric charge that corresponds to a data value to be stored. When a data value of “1” is stored, electric charge can be accumulated in a memory cell capacitor (e.g., 1aᵢⱼ). When a data value of “0” is stored, essentially no electric charge can be accumulated in a memory cell capacitor (e.g., 1aᵢⱼ).

A gate of a memory cell transistor (e.g., 1bᵢⱼ) can be connected to a word line WLᵢ. One of a source or drain of a memory cell transistor (e.g., 1bᵢⱼ) can be connected to a bit line (e.g., BLᵢⱼ) and the other source or drain can be connected to a power source potential (e.g., V_{SS}).

An example of a DRAM operation according to an embodiment will now be described. When a word line WLᵢ is activated, a memory cell transistor 1bᵢⱼ can be connected to a bit line BLⱼ. Of course, while FIG. 2 shows a memory cell transistor 1bᵢⱼ connected to a bit line BLⱼ, a different memory cell transistor 1bₖⱼ, connected to another word line WLₖ can be connected to a bit line /BLⱼ, for example.

A precharge unit 4 can include “n” precharge circuits 4₁ to 4ₙ. A precharge circuit 4ⱼ can include n-channel metal-oxide-semiconductor (NMOS) type transistors 4aⱼ, 4bⱼ, and 4cⱼ. NMOS type transistor 4aⱼ can be provided between a bit line BLⱼ and a precharge line 10. NMOS type transistor 4bⱼ can be provided between a bit line /BLⱼ and a precharge line 10. NMOS type transistor 4cⱼ can be provided between a bit line BLⱼ and a bit line /BLⱼ. A precharge activation signal EQ can be supplied to each gate of NMOS type transistors 4bⱼ, and 4cⱼ. When NMOS type transistors 4bⱼ, and 4cⱼ are activated by precharge activation signal EQ, bit line BLⱼ and /BLⱼ can be precharged to a potential V_{DD}/2.

A sense amplifier unit 5 can include “n” sense amplifier circuits 5₁ to 5ₙ. A sense amplifier 5ⱼ can include complementary MOS (CMOS) type inverters 5aⱼ and 5bⱼ, a p-channel MOS (PMOS) type transistor 5cⱼ, and an NMOS transistor 5dⱼ. In FIG. 2, a bit line /BLⱼ and output of CMOS type inverter 5bⱼ, can be connected to an input of CMOS type inverter 5aⱼ. In addition, a bit line BLⱼ and output of CMOS type inverter 5aⱼ, can be connected to an input of CMOS type inverter 5bⱼ.

CMOS type inverters 5aⱼ and 5bⱼ, can be provided between a terminal NSAPⱼ, through which a power source potential can be supplied, and a terminal NSANⱼ, through which a ground potential can be supplied. A terminal NSAPⱼ may be a power source potential supply terminal that can be connected to a sense amplifier bias line SAP through a PMOS transistor 5cⱼ. A terminal NSANⱼ may be a ground potential supply terminal that can be connected to a sense amplifier bias line SAN through an NMOS transistor 5dⱼ. A sense amplifier activation signal SASⱼ can be supplied to a gate of NMOS transistor 5dⱼ. A sense amplifier activation signal /SASⱼ can be supplied to a gate of PMOS transistor 5cⱼ.

In operation, a sense amplifier bias line SAP can be pulled to a high potential and sense amplifier bias line SAN can be pulled to a low potential. In addition, sense amplifier activation signal SASⱼ and sense amplifier activation signal /SASⱼ can be driven high and low, respectively. In such an arrangement, a high potential can be supplied to a source power supply terminal NSAPⱼ and a low potential can be supplied to a ground potential supply terminal NSANⱼ. In this way, a sense amplifier 5j can start to amplify a potential difference between bit line BLⱼ and bit line /BLⱼ.

A column switch unit 7 can include “n” column switches 7₁ to 7ₙ. A column switch 7j can be connected to bit line BLⱼ and a bit line /BLⱼ. A column switch 7j can include NMOS type transistors 7aⱼ and 7bⱼ. NMOS type transistor 7aⱼ can be provided between a bit line BLⱼ and a data bus IO, and NMOS type transistor 7bⱼ can be provided between a bit line /BLⱼ and a data bus /IO. In response to column selection signals CSW₁ to CSWₙ generated by a Y-decoder 6, a column switch unit 7 can connect a selection bit line BL and a selection bit line /BL to a data bus IO and a data bus /IO, respectively.

A Y-decoder 6 can select a selection bit line BL and selection bit line /BL in response to a Y address signal ADD_{y}. For example, a Y-decoder 6 can pull a column selection signal CSWₖ, selected from column selection signals CSW₁ to CSWₙ, to a high level. When column selection signal CSWₖ is pulled to a high level, NMOS type transistor 7aₖ can connect selection bit line BLₖ to data bus IO, and NMOS type transistor 7bₖ can connect selection bit line /BLₖ to data bus /IO. In such an arrangement, a write buffer 8 and read buffer 9 can access a selection memory cell MC.

Next, a write operation for a DRAM according to one embodiment will not be described with reference to FIGS. 1, 2 and 3. In the following description it will be assumed that a word line WLᵢ can be selected by an X-decoder 2, and a bit line BLⱼ can be selected by a Y-decoder 6. In such a case, a selection memory cell can be memory cell MCᵢⱼ. Thus, for this example a word line WLᵢ can be a selection word line, a bit line BLⱼ can be a selection bit line, and a memory cell MCᵢⱼ can be a selection memory cell. Furthermore, remaining word lines WL, bit lines BL and /BL, and memory cells MC can be considered non-selection word lines, non-selection bit lines, and non-selection memory cells MC, respectively.

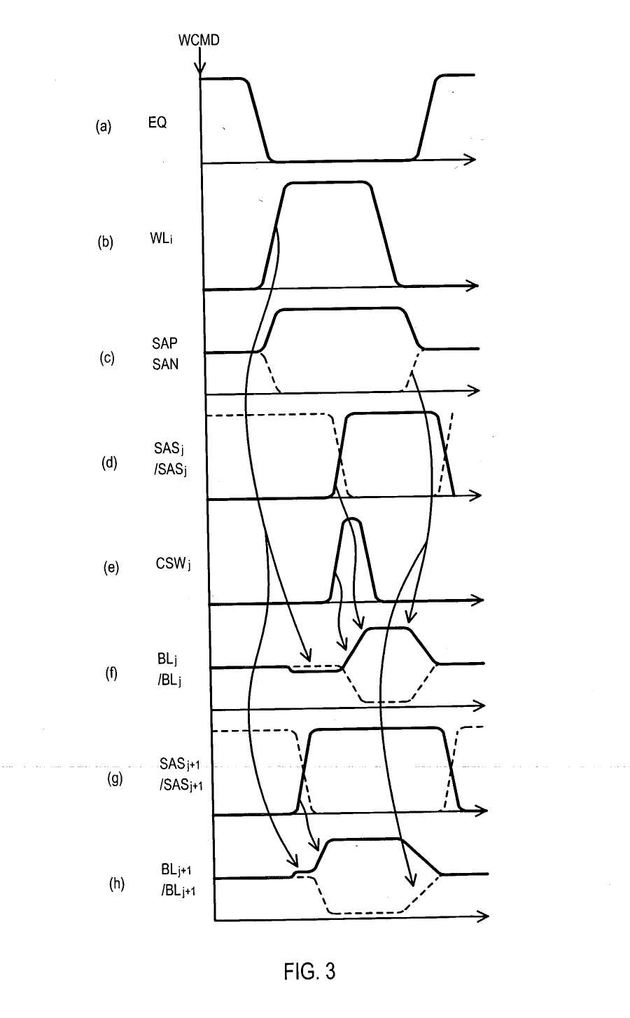

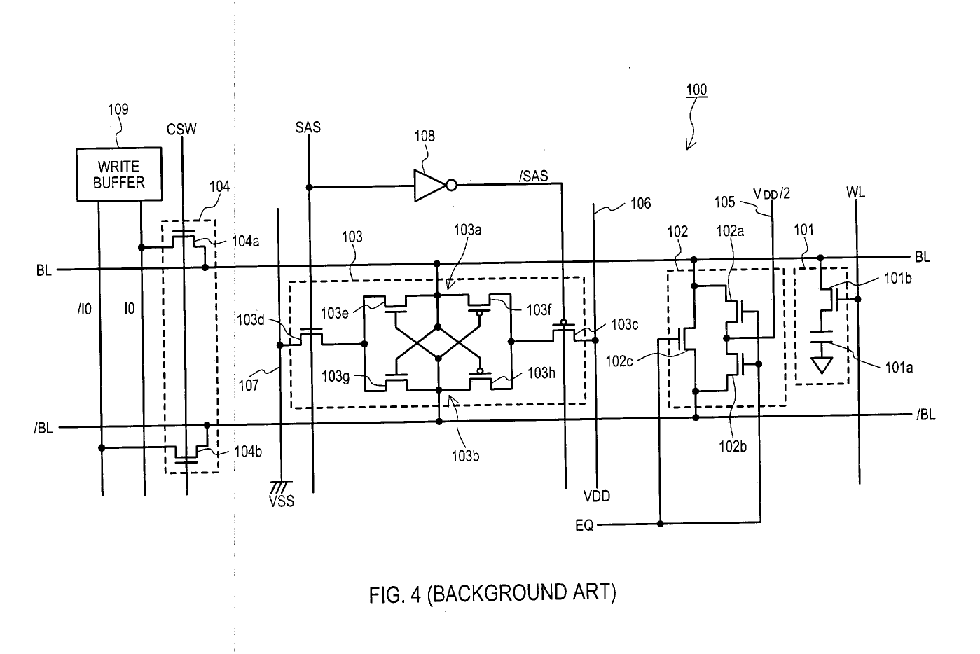

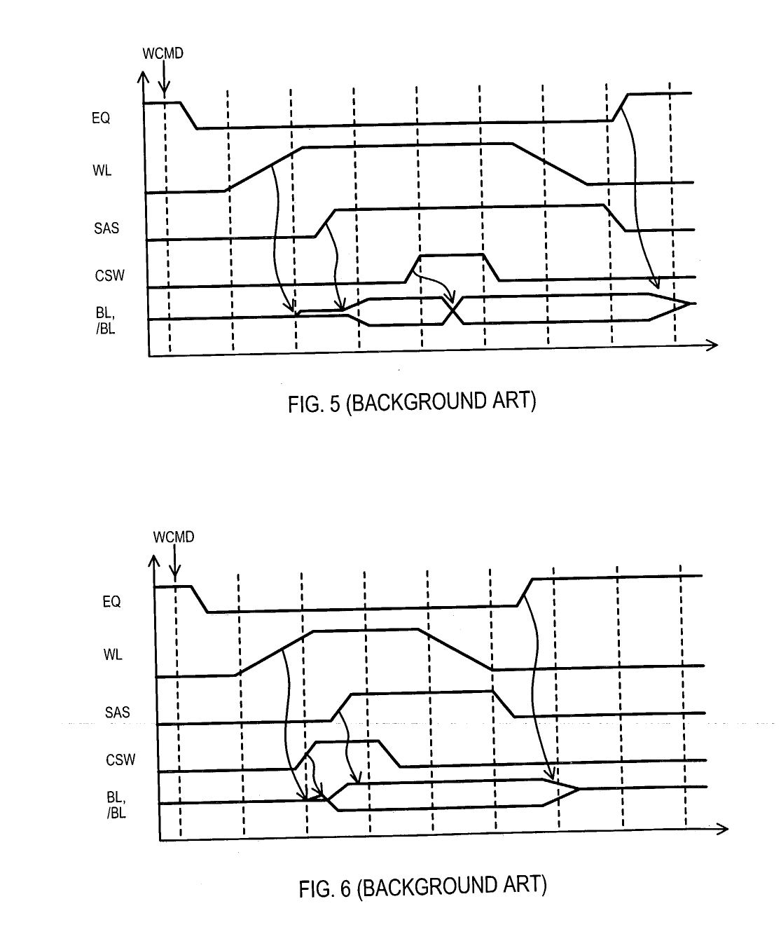

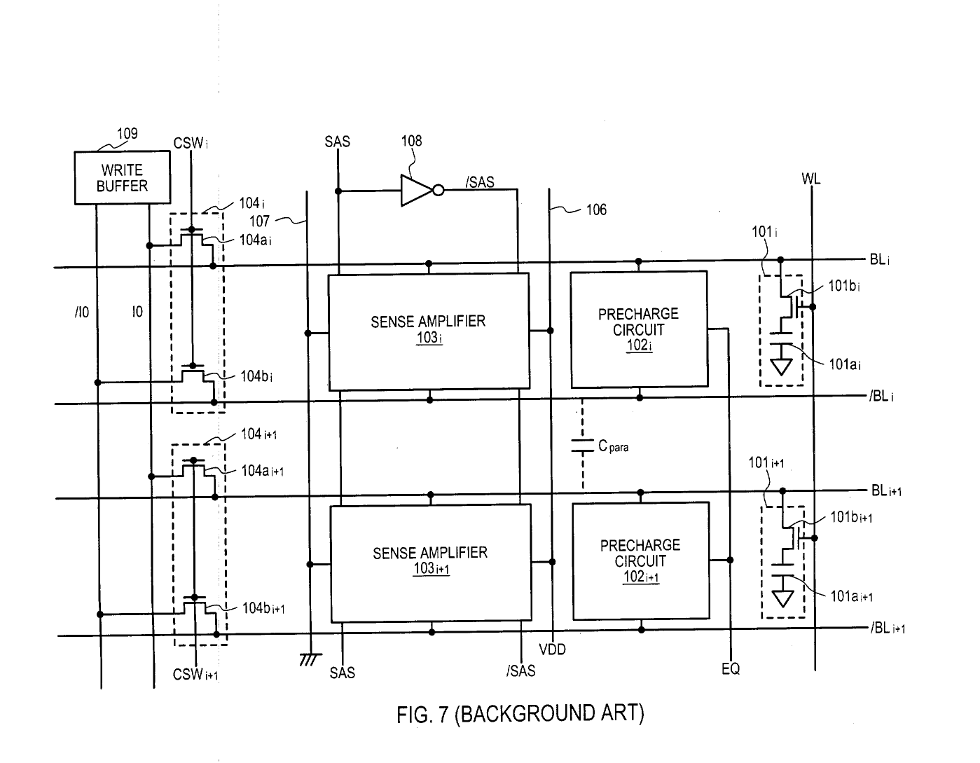

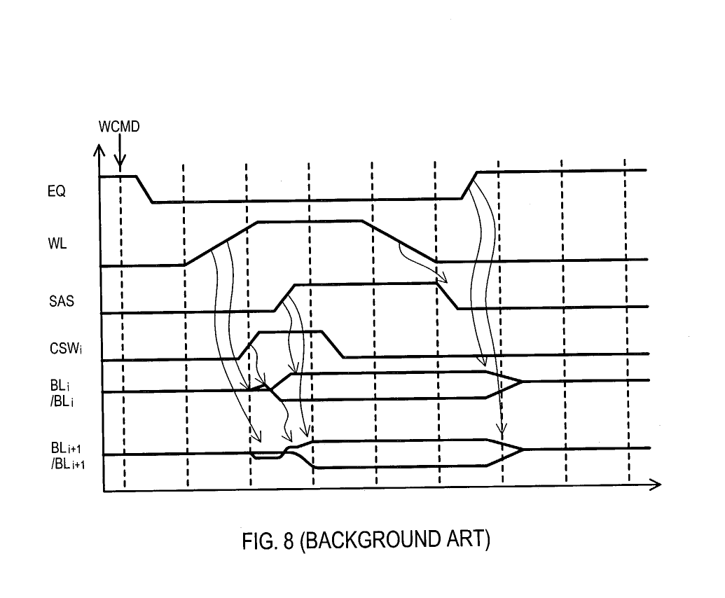

Referring now to FIG. 3, in an initial state preceding a write operation, a precharge activation signal EQ can be held at a high potential resulting in all of bit lines BL and /BL being precharged to a precharge potential (e.g., V_{DD}/2). In addition, in such an initial state, a sense amplifier bias line SAP and SAN can each be held at a precharge potential (e.g., V_{DD}/2). Still further, in an initial state, sense amplifier activation signals SAS₁ to SASₙ can be held at a low potential, while sense amplifier activation signals /SAS₁ to /SASₙ can be held at a high potential. Such an arrangement can result in sense amplifiers 5₁ to 5ₙ being in an inactive state.

At about the time when a write command WCMD is given to a DRAM of this example, a precharge activation signal EQ can be pulled to a low potential by a precharge control circuit 11. The time at which a precharge activation signal EQ is pulled to a low potential can be controlled by an operation timing control unit 13. Pulling a precharge activation signal EQ to a low potential can result in bit lines BL and /BL entering a high impedance state.

In addition, a write operation according to an embodiment may also include data buses IO and /IO being driven to potentials corresponding to a data value to be written into a selection memory cell MCᵢⱼ by write buffer 8.

Subsequently, a selection word line WLᵢ can be pulled up by word driver 3, thereby activating memory cell transistors 1b_{i,1} to 1b_{i,n} connected to word line WLᵢ. The time at which a selection word line WLᵢ is pulled up can be controlled by an operation timing control unit 13. Activation of memory cell transistors 1b_{i,1} to 1b_{i,n} can allow memory cell capacitors 1a_{i,1} to 1a_{i,n} to be electrically connected to bit lines BL₁ to BLₙ, respectively. This can result in a minute change in the potential of bit lines BL₁ to BLₙ. FIG. 3 shows the potential of selection bit lines BLⱼ and /BLⱼ, and adjacent non-selection bit lines BLⱼ₊₁ and /BLⱼ₊₁.

Subsequently, a sense amplifier bias line SAP can be pulled up to a high potential, while sense amplifier bias line SAN can be pulled down to a low potential by sense amplifier control circuit 12. The time at which sense amplifier bias lines SAP and SAN are driven to such potentials can be controlled by an operation timing control unit 13. As described above, when a sense amplifier bias line SAP is pulled to a high potential and sense amplifier bias line SAN is pulled to a low potential, sense amplifiers 5₁ to 5ₙ can be prepared to amplify potential differences between a bit line BL and a bit line /BL.

Next, sense amplifiers connected across non-selection bit lines BL and /BL can be activated by sense amplifier activation signals SAS and /SAS. Thus, a potential difference between a non-selection bit line BL and corresponding non-selection bit line /BL can be amplified. FIG. 3 shows signal waveforms for sense amplifier activation signals SASⱼ₊₁ and /SASⱼ₊₁, which are supplied to sense amplifier 5ⱼ₊₁. Sense amplifier 5ⱼ₊₁ can be connected between non-selection bit lines BLⱼ₊₁ and /BLⱼ₊₁, which are adjacent to selection bit lines BLⱼ and /BLⱼ. The activation of sense amplifier 5ⱼ₊₁ connected between non-selection bit lines BLⱼ₊₁ and /BLⱼ₊₁, can allow a potential between non-selection bit lines BLⱼ₊₁ and /BLⱼ₊₁, to be driven between high and low values according to the data value stored in non-selection memory cell MCᵢⱼ₊₁. As shown, non-selection memory cell MCᵢⱼ₊₁ can be connected to word line WLᵢ.

FIG. 3 shows the potentials of non-selection bit lines BLⱼ₊₁ and /BLⱼ₊₁. As shown, a low or high potential can be applied to a non-selection memory cell (e.g., MCᵢⱼ₊₁) connected to a word line WLᵢ according to the data stored in such a non-selection memory cell. In this way, data values may be restored for non-selection memory cells MC.

Next, a column switch selection signal CSWⱼ, supplied to column switch 7ⱼ, and sense amplifier activation signals SASⱼ and /SASⱼ, supplied to sense amplifier 5ⱼ can be activated. In the particular example of FIGS. 2 and 3, column switch selection signal CSWⱼ and sense amplifier activation signal SASⱼ can be pulled high, while sense amplifier activation signal /SASⱼ is pulled low. Activation of column switch selection signal CSWⱼ can allow selection bit lines BLⱼ and /BLⱼ to be connected to data bus IO and /IO, respectively. This can result in selection bit lines BLⱼ and /BLⱼ being driven to complementary potentials corresponding to a data value that is to be written into selection memory cell MCᵢⱼ by a write buffer 8. In addition, the activation of sense amplifier activation signals SASⱼ and /SASⱼ can allow selection bit lines BLⱼ and /BLⱼ to be driven to complementary potentials by sense amplifier 5ⱼ.

Because a delay time of column switch 7ⱼ can be shorter than that of sense amplifier 5ⱼ, even if an activation of column selection signal CSWⱼ is carried out concurrently with the activation of a sense amplifier activation signal SASⱼ, a write buffer 8 can start to drive selection bit lines BLⱼ and /BLⱼ earlier than a selection sense amplifier 5ⱼ. That is, after selection bit lines BLⱼ and /BLⱼ begin to transition according to data to be written by a write amplifier 8, a corresponding selection sense amplifier 5ⱼ can start to amplify a potential between selection bit lines BLⱼ and /BLⱼ. Potentials supplied to selection bit lines BLⱼ and /BLⱼ can thus correspond to a write data value, and such a write data value can be written to a selection memory cell MCᵢⱼ by write amplifier 8 and sense amplifier 5ⱼ.

Thus, according to the present invention, a driving of selection bit lines BLⱼ and /BLⱼ by a write buffer 8 can precede, in terms of time, a driving of selection bit lines BLⱼ and /BLⱼ by a sense amplifier 5_{j′}. In such an arrangement, a forcible inversion of selection bit lines BLⱼ and /BLⱼ by a write amplifier, as occurs in conventional approaches, can be avoided. When a sense amplifier 5j drives selection bit lines BLⱼ and /BLⱼ later than a write buffer, such a sense amplifier 5j will amplify a potential difference established by a write amplifier 8. Thus, the sense amplifier 5j will drive selection bit lines BLⱼ and /BLⱼ to a same potential direction as a write buffer 8.

In addition, a driving of selection bit lines BLⱼ and /BLⱼ as described above, can prevent destruction of data in an adjacent non-selection memory cell MC, unlike conventional approaches. When a write buffer 8 starts to drive selection bit lines BLⱼ and /BLⱼ, a potential between non-selection bit lines BL and /BL can already be established by corresponding sense amplifiers amplifying data stored in the non-selection memory cells. Thus, even if a coupling capacitance Cₚₐᵣₐ exists between a selection bit line /BLⱼ and a non-selection bit line BLⱼ₊₁, as shown in FIG. 2, destruction of data in a non-selection memory cell MC by driving of selection bit lines BLⱼ and /BLⱼ with write buffer 8 can be prevented.

The time at which a sense amplifier 5ⱼ starts to drive selection bit lines BLⱼ and /BLⱼ can correspond to when potentials of selection bit lines BLⱼ and /BLⱼ transition between high and low values by a write buffer 8 (assuming data stored in a selection memory cell is opposite to that of write data). As a result, in a write operation, selection bit lines BLⱼ and /BLⱼ are driven with the drive abilities of both a sense amplifier 5ⱼ and a write buffer 8. In this way, it can be possible to drive selection bit lines BLⱼ and /BLⱼ to complementary high/low values in a shorter period of time than conventional approaches.

Subsequently, as shown in FIG. 3, a selection word line WLᵢ can be pulled down to a low potential. As a result, memory cell capacitors 1a₁ to 1aₙ can be separated from corresponding bit lines BL.

Subsequently, potentials of sense amplifier bias lines SAP and SAN can return to a precharge potential (e.g., V_{DD}/2). At the same time, since all of bit lines BL and /BL are electrically connected to sense amplifier bias lines SAP and SAN, potentials of bit lines BL and /BL can return toward a precharge potential (e.g., V_{DD}/2).

Next, potentials of sense amplifier activation signals SAS₁ to SASₙ can return to a low value, while sense amplifier activation signals /SAS₁ to /SASₙ can return to a high value.

Referring to FIG. 2, it is preferable for sense amplifier activation signals SAS₁ to SASₙ to return low after sense amplifier bias line SAN returns to a precharge potential (e.g., V_{DD}/2). Such an arrangement can establish a potential at ground source potential supply terminals NSAN₁ to NSANₙ, preventing such terminals from being placed in a floating state. Similarly, it is preferable for sense amplifier activation signals /SAS₁ to /SASₙ to return to a high level after sense amplifier bias line SAP returns to a precharge potential (e.g., V_{DD}/2). This can establish a potential at power source potential supply terminals NSAP₁ to NSAPₙ, preventing such terminals from being placed in a floating state. Preventing ground source potential supply terminals NSAN₁ to NSANₙ and power source potential supply terminals NSAP₁ to NSAPₙ from floating can enhance the operating stability of a DRAM according to embodiments of the present invention.

Next, a precharge activation signal EQ can return to a high potential. As a result, a precharge potential (e.g., V_{DD}/2) can be supplied to bit lines BL and /BL by precharge circuits 4₁ to 4ₙ. This can return a DRAM to a previous operating state, thus completing a write operation.

A read operation in a DRAM according to the above embodiments can be similar to the operation that restores data in a non-selection memory cell MC in a write operation. After a selection word line WLᵢ has been pulled up to a high level, all of sense amplifiers 5₁ to 5ₙ can be activated by operation of sense amplifier activation signals SAS₁ to SASₙ and /SAS₁ to /SASₙ. After a potential difference between bit lines BL and /BL (established by data stored in memory cells connected to the selection word line) has been amplified by sense amplifiers 5₁ to 5ₙ, selection bit lines BLⱼ and /BLⱼ can be connected to data buses IO and /IO, respectively. In this way, data stored in selection memory cell MCᵢⱼ can be output onto data buses IO and /IO. A read buffer 9 can then output data on data buses IO and /IO.

As has been illustrated above, in a DRAM according to an embodiment, after a sense amplifier has amplified a potential difference between non-selection bit lines BL and /BL, a write buffer 8 can drive selection bit lines BLⱼ and /BLⱼ according to data to be written into a selection memory cell MCᵢⱼ. Such an arrangement can prevent data in a non-selection memory cell MC from being disturbed or destroyed.

In addition, after a write buffer 8 has started to drive selection bit lines BLⱼ and /BLⱼ, a sense amplifier 5j can start to amplify a potential difference between selection bit lines BLⱼ and /BLⱼ. Therefore, a potential difference between selection bit lines BLⱼ and /BLⱼ may not be inverted. As a result, it can be possible to reduce access time required for a write operation.

Still further, the timing at which a sense amplifier 5j starts to drive selection bit lines BLⱼ and /BLⱼ can be set to occur when selection bit lines BLⱼ and /BLⱼ transition between high and low values due to a write buffer 8 (assuming write data differs from stored data). As a result, it can be possible to further shorten access time required for a write operation.

According to the present invention, a technique has been provided that can shorten access times required for write operations in a DRAM, that may also prevent destruction in a non-selection memory cell connected to a selection word line.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A dynamic random access memory (DRAM), comprising:
a plurality of memory cells that includes transfer switches and capacitors;
a plurality of bit lines, each being electrically connected to at least one of the capacitors by the activation of a corresponding transfer switch;
a plurality of sense amplifiers connected to corresponding bit lines;
a plurality of column switches connected to the plurality of bit lines;
a decoder for selecting a selection bit line from the plurality of bit lines; and
a control unit for controlling the transfer switches, the column switches, and the sense amplifiers, in a write operation, the control unit activating the transfer switches, subsequently activating a non-selection sense amplifier that drives a non-selection bit line that is different than the selection bit line, then subsequently activating the column switch connected to the selection bit line to electrically connect a write buffer to the selection bit line, and after driving the selection bit line with the write buffer, subsequently activating a selection sense amplifier that drives the selection bit line.

2. The DRAM of claim 1, wherein:
the write buffer drives the selection bit line from an initial potential through a middle potential, about midway between a high and low logic level, when a write data value is different than a stored data value; and
the control unit activates the selection sense amplifier at essentially the same time that the selection bit line transitions through the middle potential.

3. The DRAM of claim 1, further including:
a plurality of complementary bit lines each corresponding to one of the bit lines; and
a first bias line and a second bias line connected to each of the sense amplifiers that are driven to a first power source potential and second power source potential, respectively, when the sense amplifier is activated, and driven to a predetermined precharge potential when the sense amplifiers are deactivated.

4. The DRAM of claim 3, wherein:
each sense amplifier includes
a first inverter coupled to a first terminal and second terminal, and having an input and an output coupled to one of the bit lines,
a second inverter coupled to the first terminal and second terminal, and having an output coupled to one of the complementary bit lines and the input of the first inverter and an input coupled to the output of the first inverter, and
a first switch that couples the first bias line to the first terminal when the sense amplifier is activated, and isolates the first bias line from the first terminal after the first bias line is driven to the predetermined precharge potential.

5. The DRAM of claim 4, wherein:
each sense amplifier further includes
a second switch that couples the second bias line to the second terminal when the sense amplifier is activated, and isolates the second bias line from the second terminal after the second bias line is driven to the predetermined precharge potential.

6. A dynamic random access memory (DRAM), comprising:
a plurality of memory cells;
a plurality of bit lines coupled to the plurality of memory cells;
a decoder for selecting a selection bit line from the plurality of bit lines;
a plurality of sense amplifiers coupled to the bit lines; and
a control unit for controlling the sense amplifiers in a write operation by activating a selection sense amplifier, connected to the selection bit line, at a different time than at least one non-selection sense amplifier, that is not connected to the selection bit line.

7. The DRAM of claim 6, wherein:
the control unit activates the selection sense amplifier after activating the at least one non-selection sense amplifier in the write operation.

8. The DRAM of claim 6, further including:
a plurality of column switches disposed between the bit lines and a data bus; and
the control unit, in the write operation, activates the at least one non-selection sense amplifier before activating a selection column switch coupled to the selection bit line, and activates the selection sense amplifier no sooner than the activation of the selection column switch.

9. The DRAM of claim 6, wherein:
the control unit activates the selection sense amplifier at a different time than at least one non-selection sense amplifier in response to at least a portion of an address signal.

10. The DRAM of claim 6, wherein:
the control unit activates the selection sense amplifier by activating a sense amplifier activation signal corresponding to the selection sense amplifier after activating a sense amplifier activation signal corresponding to the non-selection sense amplifier.

11. A method of writing data to a dynamic random access memory (DRAM), comprising the steps of:
(a) selecting a selection bit line from a plurality of bit lines;
(b) activating memory cell transfer switches to couple memory cell capacitors to the bit lines;
(c) after activation of the transfer switches, activating a non-selection sense amplifier coupled to a non-selection bit line to drive the non-selection bit line, the non-selection bit line being different than the selection bit line;
(d) after activating the non-selection sense amplifier, driving the selection bit line with a write amplifier through a column switch connected to the selection bit line; and
(e) after the driving of the selection bit line with the write amplifier begins, driving the selection bit line with a selection sense amplifier coupled to the selection bit line.

12. The method of writing data to a DRAM of claim 11, wherein:
step (e) is executed at essentially the same time the selection bit line transitions from an initial potential through a middle potential by operation of the write amplifier, the middle potential being essentially mid-way between a high and low logic value for the selection bit line.

13. The method of writing data to a DRAM of claim 11, wherein:
step (e) includes
(f) driving a first bias line and a second bias line connected to the sense amplifiers toward a first source potential and second source potential, respectively; and
(g) activating a first switch to supply the first source potential to a first terminal of the selection sense amplifier, and activating a second switch to supply the second source potential to a second terminal of the selection sense amplifier.

14. The method of writing data to a DRAM of claim 13, further including the steps of:
(h) after step (e), driving the first bias line and second bias line to a predetermined precharge potential that is between the first and second source potentials; and
(i) after step (h), deactivating the first switch to isolate the first source potential from the first terminal of the selection sense amplifier, and deactivating the second switch to isolate the second source potential from the second terminal of the selection sense amplifier.

15. The method of claim 11, wherein:
step (e) includes delaying a sense amplifier activation signal for the selection sense amplifier in response to an address value.

16. A method of writing data to a dynamic random access memory (DRAM), comprising the steps of:
(a) selecting a selection bit line from a plurality of bit lines;
(b) activating a plurality of transfer switches to electrically connect capacitors to corresponding bit lines; and
(c) after step (b), activating a plurality of sense amplifiers coupled to the bit lines, including activating a selection sense amplifier coupled to the selection bit line at a different time than a non-selection sense amplifier coupled to a non-selection bit line different than the selection bit line.

17. The method of writing data to a DRAM of claim 16, wherein:
step (c) includes activating the selection sense amplifier after the non-selection sense amplifier.

18. The method of writing data to a DRAM of claim 16, wherein:
step (a) includes selecting the selection bit line in response to an address value; and
step (c) includes providing different activation times of the selection sense amplifier and the non-selection sense amplifier according to at least a portion of the address value.

19. The method of writing data to a DRAM of claim 16, further including the step of:
(d) connecting a write amplifier to the selection bit line before activating the selection sense amplifier.

20. The method of writing data to a DRAM of claim 16, wherein:
step (c) includes
(c1) the non-selection sense amplifier driving the non-selection bit line according to a potential established by a non-selection memory cell coupled to the non-selection bit line, and
(c2) after step (c1), the selection sense amplifier driving the selection bit line according to a potential established by a write amplifier.
